(19) United States
(12) Patent Application Publication
(10) Pub. No.: US 2026/0052929 A1
(43) Pub. Date: Feb. 19, 2026

(54) SUBSTRATE PROCESSING APPARATUS

(71) Applicant: WONIK IPS CO., LTD., Pyeongtaek-si (KR)

(72) Inventor: Jeong Lim SON, Pyeongtaek-si (KR)

(21) Appl. No.: 19/266,600

(22) Filed: Jul. 11, 2025

(30) Foreign Application Priority Data
Aug. 16, 2024 (KR) 10-2024-0109907

(51) Int. Cl. H01L 21/67

(52) U.S. Cl. CPC H01L 21/67017; H01L 21/67109

(57) ABSTRACT

A substrate processing apparatus comprises: a heater unit (200) forming a heating space (S2) therein ; a processing vessel (300) including a vessel part (310) in which the heater unit (200) is disposed and having an opening (301) formed on a side thereof, and an opening/closing part provided in the vessel part (310) to open and close the opening (301) and having a door opening (331) formed therethrough ; and a damper unit (500) installed in the processing vessel (300) to cover the door opening (331) and transferring exhaust gas discharged from the heating space (S2) to the outside through the door opening (331).

### CROSS-REFERENCE TO RELATED APPLICATIONS

This U.S. non-provisional patent application claims priority under 35 U.S.C. § 119 of Korean Patent Application No. 10-2024-0109907, filed on Aug. 16, 2024, the entire contents of which are hereby incorporated by reference.

### FIELD OF THE INVENTION

The present invention relates to a substrate processing apparatus, and more particularly, to a substrate processing apparatus in which a high-pressure process is performed.

### BACKGROUND ART

A substrate processing apparatus is an apparatus that processes a substrate such as a wafer, and a reactor using a boat may be used to perform one or more processes such as deposition, etching, and heat treatment on a plurality of substrates.

In such a conventional reactor-type substrate processing apparatus, a single or double tube, into which a plurality of substrates are inserted by a boat to perform substrate processing, is applied, and a heater is provided at the outermost part to supply heat to form process temperature atmosphere.

Meanwhile, for various processes on a substrate, particularly for annealing process that improves film quality through recrystallization of the substrate surface by removing residues remaining on and within the substrate surface, it may be necessary to perform substrate processing by creating high temperature of 800° C. or more and high pressure of 2 ATM or more, as required.

However, conventional substrate processing apparatuses applied a double tube for protection in case of tube breakage due to the creation of a high-pressure state of 2 ATM or more. However, in the case of quartz material, there is a problem that its durability is weak due to high risk of damage under high-pressure environment, and contamination due to gas leakage may occur in case of damage.

Furthermore, if the material of the double tube is reinforced in response to this, there is a problem that sufficient high-temperature condition for substrate processing is difficult to achieve, as the heat transfer rate is low due to the material, making it difficult to receive heat from a heater located at the outermost part.

Accordingly, a heater was placed inside the tube to increase heating efficiency for process temperature with sufficient rigidity against high pressure. However, in this case, there is a problem that smooth supply and exhaust of cooling gas into the heater, which is supplied and exhausted to cool the heater and surrounding components after high-temperature process, is difficult.

Furthermore, as components for supplying and exhausting cooling gas are arranged to be connected to the heater within the tube, there is a problem that maintenance and management for each component are difficult.

In addition, since piping and valves for supplying cooling gas are additionally provided to protrude from separate locations outside the tube, there is a problem that space efficiency is reduced.

### SUMMARY OF THE INVENTION

The object of the present invention is to provide a substrate processing apparatus in which high-pressure process is performed, enabling smooth supply of cooling gas into the heater, in order to solve the above problems.

The present invention has been created to achieve the above object of the present invention. The present invention discloses a substrate processing apparatus comprising: a heater unit (200) forming a heating space (S2) therein; a processing vessel (300) including a vessel part (310) in which the heater unit (200) is disposed and having an opening (301) formed on a side thereof, and an opening/closing part provided in the vessel part (310) to open and close the opening (301) and having a door opening (331) formed therethrough ; and a damper unit (500) installed in the processing vessel (300) to cover the door opening (331) and transferring exhaust gas discharged from the heating space (S2) to the outside through the door opening (331).

The apparatus may include an inner tube (100) disposed in the heater unit (200) to form the heating space (S2) between itself and the heater unit (200), and forming a processing space (S1) for substrate processing therein.

The opening/closing part may open the opening (301) to allow external access to the inside of the processing vessel (300) for maintenance of the damper unit (500).

The opening/closing part may include a flange part (320) protruding from the vessel part (310) at a position corresponding to the opening (301), and an opening/closing door part (330) installed on the flange part (320) to open and close the opening (301).

The damper unit (500) may have one end coupled to the heater unit (200) so as to communicate with the heating space (S2), and the other end coupled to the opening/closing door part (330) so as to cover the door opening (331).

The apparatus may further include a heat exchange module (90) coupled to the opening/closing part outside the processing vessel (300) so as to communicate with the damper unit (500) through the door opening (331), and performing heat exchange with the exhaust gas.

The apparatus may further include a cooling gas supply unit (400) installed through the opening/closing part to supply cooling gas to the heating space (S2).

The cooling gas supply unit (400) may be installed to penetrate the lower side of the flange part (320).

The cooling gas supply unit (400) may include an external supply pipe (410) installed on the lower side of the flange part (320) to transfer the cooling gas from outside, and an internal supply pipe (420) installed inside the flange part (320) so as to communicate with the external supply pipe (410), with one end coupled to the side of the heater unit (200) and the other end coupled to the inner surface of the flange part (320).

The external supply pipe (410) may be formed in an ‘L’ shape in front view with respect to the opening/closing door part (330).

The cooling gas supply unit (400) may be provided as a pair in both lateral directions with respect to the front center of the flange part (320).

The flange part (320) and the opening/closing door part (330) may have a rectangular cross-section corresponding to the damper unit (500).

The heater unit (200) may include a side insulation part (210) forming the heating space (S2), a heating part (220) provided on the inner surface of the side insulation part (210) to generate heat according to applied power, and an upper insulation part (230) provided on the upper end of the side insulation part (210), having an exhaust flow path (231) formed therein for discharging exhaust gas from the heating space (S2), and coupled to the damper unit (500).

The internal supply pipe (420) may be coupled at the boundary between the side insulation part (210) and the upper insulation part (230) so as to communicate with the heating space (S2).

The internal supply pipe (420) may be coupled at a position corresponding to a groove (201) formed on the outer side of the side insulation part (210) with a step inward, and communicating with the heating space (S2).

The damper unit (500) may be coupled to the upper insulation part (230) so as to communicate with the exhaust flow path (231).

The internal supply pipe (420) may be disposed below the damper unit (500) inside the flange part (320).

The apparatus may further include a cooling unit (600) installed to surround at least a portion of the flange part (320).

The cooling unit (600) may include a first cooling pipe (610) installed on the outer surface of the processing vessel (300) with heat medium flowing therein, and a second cooling pipe (620) extending from the first cooling pipe (610) and installed to surround at least a portion of the flange part (320) with heat medium flowing therein.

The internal space (S3) between the processing vessel (300) and the heater unit (200), and the heating space (S2) may communicate with each other.

The inner tube (100) may include quartz, and the processing vessel (300) may include Steel Use Stainless (SUS).

The internal space (S3) between the processing vessel (300) and the heater unit (200) may be maintained at higher pressure than the processing space (S1).

The internal space (S3) between the processing vessel (300) and the heater unit (200) may maintain pressure of 2 ATM or more during at least a portion of the process performed in the processing space (S1).

The substrate processing apparatus according to the present invention has the advantage that the protection function is improved as a processing vessel that can be used without damage even at high pressure of 2 ATM or more is applied to the outermost part, and heating efficiency is increased through the proximity of the heater unit to the inner tube.

Further, the substrate processing apparatus according to the present invention has the advantage that the damper unit and the cooling gas supply unit, which are disposed inside the processing vessel and connected to the heater unit, are accessible through the opening of the side opening/closing door part of the processing vessel, thereby facilitating maintenance and management of each component.

In particular, the substrate processing apparatus according to the present invention has the advantage that maintenance is easy through access to the damper unit installed therein via the side opening/closing part of the processing vessel, and also, the opening/closing part acts as an exhaust flow path for exhaust gas discharged from the damper unit to the outside, thereby eliminating additional openings for separate external exhaust.

Further, in the substrate processing apparatus according to the present invention, as the cooling gas supply unit is installed through the opening/closing part provided in the processing vessel, a separate additional protruding structure for supplying cooling gas to the outside of the processing vessel is omitted, which has the advantage of simplifying the installation structure and increasing space efficiency.

### BRIEF DESCRIPTION OF THE DRAWINGS

FIG. 1 is a perspective view showing a substrate processing apparatus according to the present invention.

FIG. 2 is a cross-sectional view showing the interior of the substrate processing apparatus according to FIG. 1.

FIG. 3 is an enlarged cross-sectional view showing the connection appearance of each of the damper unit and the cooling gas supply unit in the substrate processing apparatus according to FIG. 1.

FIG. 4 is a perspective view showing the installation appearance of the damper unit and the cooling gas supply unit in the substrate processing apparatus according to FIG. 1.

### DETAILED DESCRIPTION OF THE PREFERRED EMBODIMENTS

DETAILED DESCRIPTION OF THE INVENTION Hereinafter, the substrate processing apparatus according to the present invention will be described in detail with reference to the accompanying drawings.

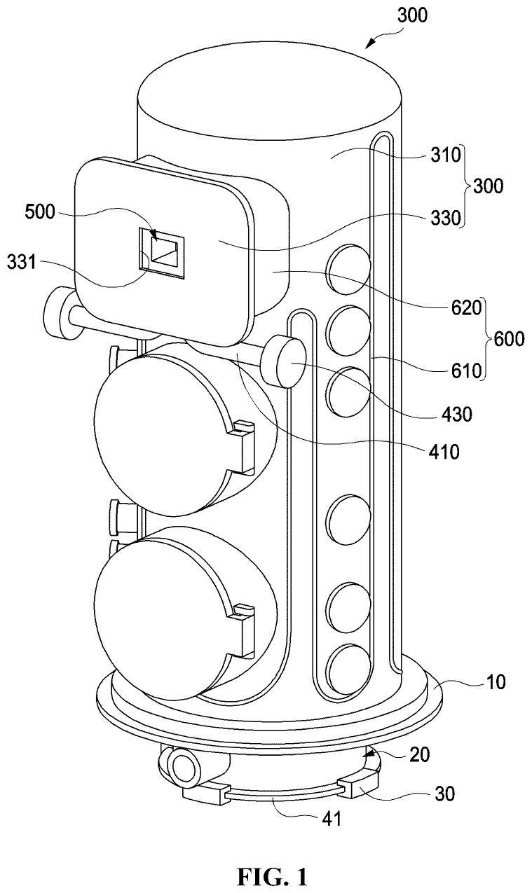

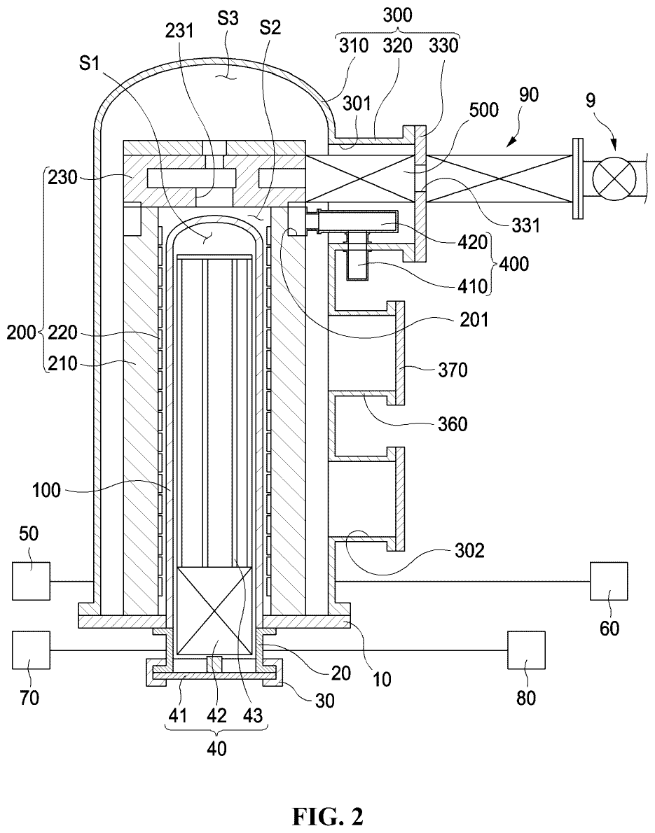

As shown in FIGS. 1 and 2, the substrate processing apparatus according to the present invention includes: a heater unit (200) forming a heating space (S2) therein ; a processing vessel (300) including a vessel part (310) in which the heater unit (200) is disposed and having an opening (301) formed on a side thereof, and an opening/closing part provided in the vessel part (310) to open and close the opening (301) and having a door opening (331) formed therethrough ; and a damper unit (500) installed in the processing vessel (300) to cover the door opening (331) and transferring exhaust gas discharged from the heating space (S2) to the outside through the door opening (331).

Further, the present invention may further include a cooling gas supply unit (400) installed through the opening/closing part to supply cooling gas to the heating space (S2).

Further, the present invention may further include an inner tube (100) disposed in the heater unit (200) to form the heating space (S2) between itself and the heater unit (200), and forming a processing space (S1) for substrate processing therein.

Further, the present invention may further include a damper unit (500) installed in the flange part (320) to transfer exhaust gas discharged from the heating space (S2) to the outside.

Further, the present invention may further include a cooling unit (600) installed to surround at least a portion of the flange part (320).

Here, the substrate to be processed can be understood to include all substrates, such as those used in display substrates like LEDs, LCDs, OLEDs, semiconductor substrates, solar cell substrates, and glass substrates.

Further, any conventionally disclosed process can be applied as the process performed by the substrate processing apparatus according to the present invention, as long as it is a process for treating a substrate. For example, processes such as deposition, etching, and heat treatment can be performed.

For example, the substrate processing apparatus according to the present invention can perform annealing to improve the film quality of a substrate such as a wafer, and in particular, it can effectively improve film quality by promoting recrystallization or migration of the substrate surface through effective removal of impurities remaining on or weakly bonded to the surface and interior of the substrate or thin film.

In this case, the substrate processing apparatus according to the present invention can repeatedly perform a high-pressure process, for example, high pressure of 2 ATM or more, which is higher than atmospheric pressure, in the processing space (S1) where substrate processing is performed, and a low-pressure process in a vacuum state, i.e., lower than atmospheric pressure. If necessary, heat treatment at high temperature of 800° C. or more can be performed.

The inner tube (100) is a component that forms a processing space (S1) therein, and various configurations are possible.

In this case, the inner tube (100) may be a vertical cylindrical shape with a dome-shaped ceiling, forming a processing space (S1) therein, with its lower part open so that a boat (40) loaded with a plurality of substrates, described later, can be loaded and unloaded.

That is, the inner tube (100) has its lower part open, allowing a boat (40) loaded with a plurality of substrates to be inserted through the lower part, thereby forming a sealed processing space (S1) where substrate processing can be performed. After the substrate processing is completed, the boat (40) can be lowered and unloaded.

In this case, the boat (40) may include a support part (43) that supports a plurality of substrates spaced apart vertically, an insulation part (42) provided below the support part (43) to prevent heat loss from the processing space (S1) to the outside, and a cap flange (41) below the insulation part (42) that supports the insulation part (42) and the substrate support part (43).

Accordingly, when the boat (40) is raised and loaded into the processing space (S1) within the inner tube (100), the cap flange (41) can be in close contact with the lower end of the manifold (20), and they can be coupled to each other through a clamp (30) that clamps the edges of the cap flange (41) and the lower end of the manifold (20) to form a sealed processing space (S1).

In particular, the clamp (30), by clamping and fixing the manifold (20) and the cap flange (41), prevents the cap flange (41) from moving downward due to the internal high pressure when a high-pressure process of 2 ATM or more is performed in the processing space (S1), and can maintain the sealed state of the processing space (S1).

Meanwhile, the inner tube (100) may be supported by a manifold (20) installed at its open lower end and communicate with the manifold (20). In this case, process gas can be received from an external first gas supply unit (80) through a supply port formed in the manifold (20).

Further, the inner tube (100) may have process gas discharged to the external first gas exhaust unit (70) through an exhaust port formed in the manifold (20), thereby exhausting the processing space (S1).

The inner tube (100) is a non-metallic material, which may be made of quartz, and as described above, it may have a dome-shaped ceiling, but it is not limited thereto, and it may also be configured in a cylindrical shape with a flat ceiling.

The heater unit (200) may be configured to surround at least a portion of the inner tube (100) and form a heating space (S2) between itself and the inner tube (100).

That is, the heater unit (200) may be configured to have the inner tube (100) disposed inside it, forming a heating space (S2) between itself and the inner tube (100), and heating it to form the interior of the processing space (S1) into a process temperature atmosphere.

To this end, the heater unit (200) may include a side insulation part (210) disposed to surround the inner tube (100), a heating part (220) provided on the inner surface of the side insulation part (210) to generate heat according to applied power, and an upper insulation part (230) provided on the upper end of the side insulation part (210), having an exhaust flow path (231) formed therein for discharging exhaust gas from the heating space (S2), and coupled to the damper unit (500).

The side insulation part (210) is a component disposed to surround the inner tube (100) and may form the side surface of the heater unit (200).

In this case, the side insulation part (210) may be configured to form its side surface through a plurality of insulating materials, and the heating part (220) may be disposed on its inner surface to concentrate heat into the heating space (S2) and the processing space (S1) and minimize heat loss to the outside of the side insulation part (210).

Further, the side insulation part (210) may be formed by stacking a plurality of annular members, and in this case, a plurality of gas supply ports (not shown) may be formed to penetrate radially between or in the annular members, so that the internal space (S3) and the heating space (S2) communicate with each other, and cooling gas supplied from the cooling gas supply unit (400) can be guided to be transferred into the heating space (S2).

The heating part (220) is a component provided on the inner surface of the side insulation part (210) to generate heat according to applied power, and various configurations are possible.

In this case, the heating part (220) is a component that generates heat through resistance heat generated by a resistor to which electric power is applied, and the amount of heat generation and temperature can be adjusted by appropriately controlling the applied power.

Meanwhile, the heating part (220) may be provided in a plurality of units in the vertical direction on the inner surface of the side insulation part (210), and its ends may penetrate the side insulation part (210) to receive power from the outside through terminal parts provided outside the side insulation part (210).

The upper insulation part (230) may be configured to be provided on the upper end of the side insulation part (210) and have an exhaust flow path (231) formed therein for discharging exhaust gas from the heating space (S2).

That is, the upper insulation part (230) is a component that forms the upper end and ceiling of the heater unit (200), and by being provided on the upper end of the side insulation part (210) including a plurality of insulation plates, it can prevent heat loss upwards from the heating space (S2).

Meanwhile, the upper insulation part (230) may have an exhaust flow path (231) formed for the external discharge of cooling gas supplied to the heating space (S2). For example, the exhaust flow path (231) may be formed to extend from an exhaust port formed on the bottom surface of the upper insulation part (230), i.e., the ceiling surface of the heater unit (200), to the side surface of the upper insulation part (230), thereby guiding the exhaust gas, which is the cooling gas that has completed heat exchange, to be discharged to the outside.

In this case, the upper insulation part (230) may have a damper unit (500), described later, coupled to its side so as to communicate with the exhaust flow path (231). This can guide the exhaust gas, which is cooling gas supplied to the heating space (S2) and has performed heat exchange, to be transferred to the damper unit (500) through the exhaust flow path (231).

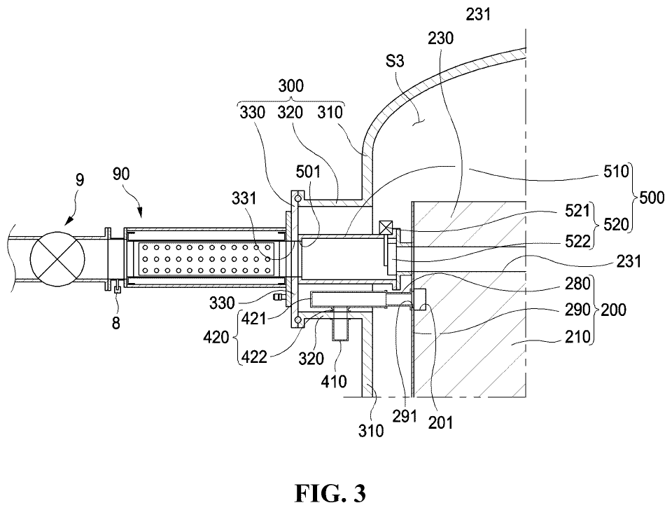

Further, as shown in FIG. 3, the heater unit (200) may include a cover part (290) disposed at the outermost part of the side insulation part (230) and having a through-hole (291) formed therein to communicate with a cooling gas supply unit (400), described later, and a connecting flange (280) formed to protrude corresponding to the through-hole (291) of the cover part (290) and coupled to the cooling gas supply unit (400).

In this case, the cover part (290) is a component forming the outermost surface of the heater unit (200), and may be configured as an insulating material like the side insulation part (210) and disposed at the outermost part, or as another example, it may be applied as a cover provided to wrap the side insulation part (210).

The cover part (290) may be configured to have a through-hole (291) formed therein to communicate with the cooling gas supply unit (400). In particular, the through-hole (291) may be formed at a position corresponding to a groove (201) formed on the outer surface of the side insulation part (210) with an inward step, and communicating with the heating space (S2), thereby transferring cooling gas from the cooling gas supply unit (400) toward the groove (201).

Accordingly, the cover part (290) may form a cooling gas supply flow path between itself and the groove (201) formed along the circumference of the heater unit (200).

Meanwhile, the connecting flange (280) protrudes from the outside of the cover part (290) corresponding to the through-hole (291), and may be coupled to a cooling gas supply unit (400) described later.

In this case, a sealing member (not shown) may be provided between the connecting flange (280) and the cooling gas supply unit (400).

The processing vessel (300) is a component in which the inner tube (100) and the heater unit (200) are disposed, and forms an internal space (S3) between itself and the heater unit (200). Various configurations are possible.

That is, the processing vessel (300) is a component installed to surround the heater unit (200), which can form an internal space (S3) between itself and the heater unit (200), and can be a vertical cylindrical structure with a dome-shaped ceiling, corresponding to the aforementioned inner tube (100).

Meanwhile, the processing vessel (300) may be disposed outside the inner tube (100), where high-temperature and high-pressure substrate processing is performed, and the heater unit (200), which surrounds the inner tube (100), thereby forming an internal space (S3) as a protective space. Accordingly, it can be configured to prevent external leakage of process gas due to damage to the inner tube (100) during high-pressure substrate processing and to have sufficient rigidity against high pressure.

To this end, the processing vessel (300) may be made of a metal material, and for example, may include steel use stainless (SUS).

Meanwhile, the internal space (S3) formed between the processing vessel (300) and the heater unit (200) can be maintained at higher pressure than the processing space (S1) to act as a protective space, as described above. Since the heater unit (200) is not sealed and allows gas to pass through, it can communicate with the heating space (S2).

That is, the internal space (S3) can be maintained at pressure of 2 ATM or more during at least a portion of the process performed in the processing space (S1), and when the heating space (S2) is maintained at temperature of 800° C. or more during at least a portion of the process performed in the processing space (S1) due to the heating of the heating space (S2), it can be maintained at similar temperature condition.

Meanwhile, the processing vessel (300) has one or more separate supply ports and one or more exhaust ports formed on its side, and each is connected to a second gas supply unit (60) and a second gas exhaust unit (50) to receive gas into the internal space (S3) from outside and to exhaust the internal space (S3).

Further, the heater unit (200) and the processing vessel (300) are each configured with an open lower end, and their open lower ends can be supported and installed on a base unit (10). In this case, the aforementioned manifold (20) can be coupled and installed on the bottom surface of the base unit (10).

Meanwhile, the processing vessel (300) includes a vessel part (310) in which the heater unit (200) is disposed, forming an internal space (S3) between itself and the heater unit (200), and having an opening (301) formed on a side to allow external access to the internal space (S3), and an opening/closing part provided in the vessel part (310) to open and close the opening (301).

The vessel part (310) is a component that forms the internal space (S3) and has an opening (301) formed on its side, and various configurations are possible.

For example, the vessel part (310) may be made of SUS material and have a dome-shaped ceiling, and may be provided such that the heater unit (200) and the inner tube (100) are inserted therein. Its lower end may be open and supported and installed on the base unit (100).

In this case, the vessel part (310) may have an opening (301) formed on its side, which allows access for maintenance of the damper unit (500) installed in the internal space (S3) for external discharge of cooling gas supplied to the heating space (S2).

The flange part (320) may be formed as a component protruding from the vessel part (310) at a position corresponding to the opening (301), and the opening/closing door part (330) may be installed to open and close the opening (301).

In this case, the opening/closing door part (330) may be configured to be coupled to and separable from the flange part (320) with a first sealing member (332) interposed therebetween, thereby closing and opening the opening (301).

Meanwhile, the opening/closing door part (330) may be coupled to the flange part (320) via bolting with a first sealing member (332) interposed therebetween. A hinge part may be provided at one end, allowing the opening (301) to be opened by hinge rotation after the bolts are loosened.

Further, the opening/closing door part (330) may further include a door opening (331) formed therethrough to allow communication between a damper unit (500), described later, and the outside.

That is, with the door opening (331) formed therethrough, the opening/closing door part (330) can have the damper unit (500) coupled to its inner surface to cover the door opening (331), and an external pipe coupled to its outer surface to cover the door opening (331), thereby allowing communication between the damper unit (500) and the heat exchange module (90).

In this case, the heat exchange module (90) can control the exhaust gas discharge through an external pipe and a valve (9) coupled and installed on the opposite side of the damper unit (500).

Further, the opening/closing door part (330) and the flange part (320) where the opening/closing door part (330) is installed may be formed in a rectangular shape when viewed from the front, corresponding to the damper unit (500) described later.

Further, the processing vessel (300) according to the present invention may further include at least one additional opening (302) formed on the outer surface of the vessel part (310) in addition to the aforementioned opening (301), and a side flange (360) and a door part (370) installed on the side flange (360) to open and close the opening (302) corresponding to the opening (302).

That is, the vessel part (310) may have at least one additional opening (302) formed below the opening (301) formed on its side to allow access to the internal space (S3), and a side flange (360) and a door part (370) for opening and closing the opening (302) may be further provided.

In this case, the side flange (360) and the door part (370) are components for maintenance and management of the heater unit (200) through access to the internal space (S3). In particular, they may be provided to allow access for maintenance and management of terminal parts and power supply parts installed to supply power to the heater unit (200).

The damper unit (500) may have one end coupled to the upper insulation part (230) so as to communicate with the exhaust flow path (231), and the other end coupled to the opening/closing door part (330). Various configurations are possible.

The damper unit (500) is a component installed between the heater unit (200) and the external heat exchange module to communicate the heating space (S2) and the heat exchange module. Various configurations are possible.

For example, at least a portion of the damper unit (500) may be disposed within the flange part (320). One end of the damper unit (500) may be coupled to the heater unit (200), and the other end of the damper unit (500) may be coupled to the opening/closing door part (330) by covering the door opening (331) so as to communicate with the external heat exchange module.

That is, the damper unit (500) has an end opening (501) formed at the end in the direction of the opening/closing door part (330), and is disposed to cover the door opening (331), thereby forming a flow path for exhaust gas in the order of the damper unit (500), the door opening (331) of the opening/closing door part (330), and the heat exchange module (90).

In this case, the end opening (501) may be the same size as the door opening (331), or as another example, it may be larger or smaller than the door opening (331).

For example, the damper unit (500) may include a damper body (510) having a flow path for exhaust gas formed therein, and a flow rate adjusting unit (520) provided within the damper body (510) to adjust the degree of opening of the flow path.

More specifically, the damper unit (500) may have a damper body (510), in which a flow path for exhaust gas discharged through the exhaust flow path (231) is formed. One end of the damper body (510) may be coupled to an exhaust flow path flange formed on the side wall of the upper insulation part (230) so as to communicate with the exhaust flow path (231), and the other end of the damper unit (500) may be coupled to the opening/closing door part (330).

In this case, the damper unit (500), as a flow rate adjusting unit (520), may include a driving unit (521) that generates power, such as a motor or actuator, to drive a blade (522), and a blade (522) that controls the exhaust gas flow in the flow path through the driving unit (521), thereby appropriately adjusting the flow rate of exhaust gas discharged through the damper unit (500).

Meanwhile, the damper unit (500) may be configured to be openable and closable, but it may not be completely shut off and may be in constant communication with the exhaust flow path (231) and the heat exchange module (90) described later. Accordingly, since it is in constant communication with the heating space (S2) and the internal space (S3) communicating with the heating space (S2), the interior can be maintained at high pressure, and high-temperature exhaust gas can be transferred.

The cooling gas supply unit (400) is a component installed through the opening/closing part to supply cooling gas to the inside of the processing vessel (300), and various configurations are possible.

In this case, the cooling gas supply unit (400) may supply cooling gas to the heating space (S2) for cooling the heating space (S2).

In this case, the cooling gas supply unit (400) may be installed through the opening/closing part to supply cooling gas to the heating space (S2). More specifically, it may be installed from outside to penetrate the lower side of the flange part (320) and connect to the heater unit (200).

For example, the cooling gas supply unit (400) may include an external supply pipe (410) installed on the lower side of the flange part (320) to transfer cooling gas from outside, and an internal supply pipe (420) installed inside the flange part (320) so as to communicate with the external supply pipe (410), with one end coupled to the side of the heater unit (200) and the other end coupled to the inner surface of the flange part (320).

The external supply pipe (410) is a component installed by being coupled to the lower side of the flange part (320) to transfer cooling gas from outside, and various configurations are possible.

In this case, the cooling gas supplied through the external supply pipe (410) is external air, and the external supply pipe (410) can open and close a valve (430) provided at its end to receive external air and transfer it to the internal gas supply pipe (420).

Further, as another example, the external supply pipe (410) may be connected to a separately provided cooling gas supply source (not shown) with a valve (430) interposed therebetween, to receive cooling gas at a flow rate controlled by the valve (430) and supply it to the internal supply pipe (420).

In this case, the external supply pipe (410) may be installed to be coupled to the bottom surface of the rectangular flange part (320). More specifically, it may be installed to extend laterally from the flange part (320) so as not to protrude to the opposite side of the vessel part (310) with respect to the flange part (320) in a plane.

That is, the external supply pipe (410) may be formed in an ‘L’ shape in front view with respect to the opening/closing door part (330), which has the advantage of increasing space efficiency and enabling the application of a compact apparatus structure.

The internal supply pipe (420) is a component installed inside the flange part (320) to communicate with the external supply pipe (410), with one end coupled to the side of the heater unit (200) and the other end coupled to the inner surface of the flange part (320). Various configurations are possible.

That is, as shown in FIG. 3, the internal supply pipe (420) is a component that communicates with the external supply pipe (410) and transfers cooling gas to the heater unit (200) side, and at least a portion thereof may be disposed within the flange part (320).

For example, the internal supply pipe (420) may include a first internal supply pipe (421) forming a flow path for cooling gas transfer therein and coupled to the aforementioned connecting flange (280), and a second internal supply pipe (422) having one end coupled to the first internal supply pipe (421) and the other end corresponding to the external supply pipe (410) and coupled to the inner surface of the flange part (320) for installation.

In this case, the second internal supply pipe (422) is disposed between the bottom surface of the hexahedral first internal supply pipe (421) and the inner surface of the flange part (320), thereby transferring cooling gas supplied from the bottom surface of the flange part (320) to the first internal supply pipe (421), and guiding the cooling gas to move horizontally through the first internal supply pipe (421) to the heater unit (200) side.

Meanwhile, the internal supply pipe (420) can transfer cooling gas to the heating space (S2) via the groove (201) and the side insulation part (210) through coupling with the aforementioned connecting flange (280). In this case, a separate flow path may be formed in the vertical direction of the side insulation part (210) so that the cooling gas is evenly transferred toward the heating space (S2) in the vertical direction of the side insulation part (210).

Meanwhile, the internal supply pipe (420) may be coupled at a height corresponding to the boundary between the side insulation part (210) and the upper insulation part (230) so as to communicate with the heating space (S2). Also, as described above, it may be coupled at a position corresponding to the groove (201) formed on the outer side of the side insulation part (210) with an inward step, and communicating with the heating space (S2).

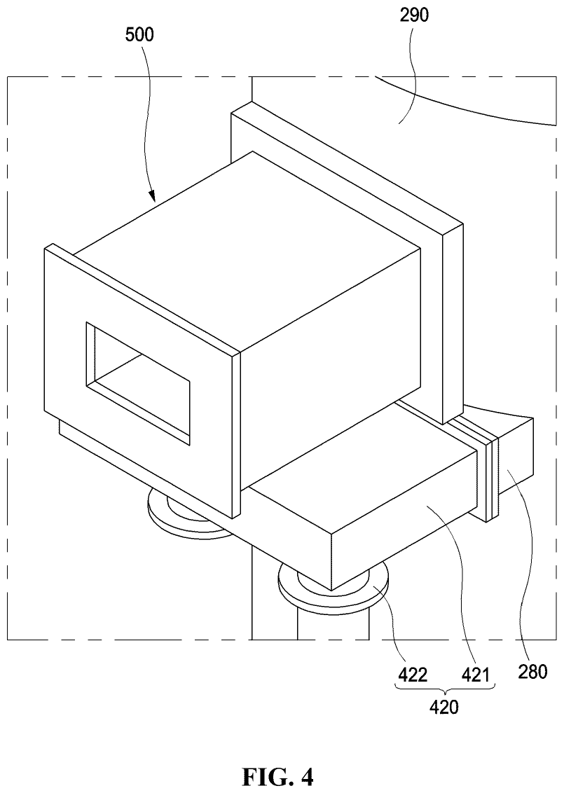

Further, as shown in FIGS. 3 and 4, the internal supply pipe (420) may be disposed below the damper unit (500) inside the flange part (320).

Meanwhile, the cooling gas supply unit (400) including the external supply pipe (410) and the internal supply pipe (420) may be provided as a pair in both lateral directions with respect to the front center of the flange part (320), and in this case, the external supply pipes (410) may extend in opposite directions to each other.

In this case, the external supply pipe (410) and the internal supply pipe (420) may be formed as a symmetrical pair with respect to the center of the damper unit (500) and the opening/closing door part (330) in front view.

The cooling unit (600) is a component installed to surround at least a portion of the flange part (320) and cool the flange part (320), and various configurations are possible.

Further, the cooling unit (600) may be installed in contact with the outer surface of the vessel part (310) and configured to have heat medium flowing therein, and can lower the temperature of the vessel part (310) through heat exchange between the heat medium and the vessel part (310).

For example, the cooling unit (600) may include a first cooling pipe (610) installed on the outer surface of the processing vessel (300) with heat medium flowing therein, and a second cooling pipe (620) extending from the first cooling pipe (610) and installed to surround at least a portion of the flange part (320) with heat medium flowing therein. Accordingly, the first cooling pipe (610) and the second cooling pipe (620) can form a single heat medium flow path.

In this case, the heat medium is supplied to the second cooling pipe (620) of the flange part (320), which has relatively high temperature due to the installation of the damper unit (500), flows along the second cooling pipe (620), then continuously flows through the first cooling pipe (610), and is discharged to an external heat exchanger to increase cooling efficiency.

The heat exchange module (90) is a component installed outside the heater unit (200) to be in constant communication with the heating space (S2), and performs heat exchange with exhaust gas discharged from the heating space (S2). Various configurations are possible.

More specifically, as shown in FIG. 3, the heat exchange module (90) may be a radiator configuration that performs heat exchange to cool high-temperature exhaust gas. After substrate processing due to heating by the heater unit (200), cooling gas is supplied to the heating space (S2) through the processing vessel (300) for rapid cooling of the heating space (S2), inner tube (100), etc. At this time, the supplied cooling gas performs heat exchange in the heating space (S2) and is then discharged through the exhaust flow path (231).

In particular, the heat exchange module (90) must cool and discharge high-temperature and high-pressure exhaust gas to the outside. Therefore, it is impossible to apply a sealing member due to the high-temperature and high-pressure atmosphere, making it difficult to maintain a complete seal with the aforementioned damper unit (500) and internal space (S3). Accordingly, it can be applied in a structure that is in constant communication with the heating space (S2).

To this end, the heat exchange module (90) can be coupled and installed to the processing vessel (300) from outside the processing vessel (300) to cool and discharge exhaust gas to the outside.

For example, the heat exchange module (90) may be installed on the opening/closing door part (330) by covering the door opening (331) so as to communicate with the heating space (S2) through the door opening (331). This allows it to be directly connected to and communicate with the aforementioned damper unit (500).

Meanwhile, the heat exchange module (90), due to constant communication with the heating space (S2) described above, may have high pressure formed inside during substrate processing in the processing space (S1), and high-temperature exhaust gas may be transferred after substrate processing is completed.

Accordingly, a configuration with reinforced rigidity can be applied to enable stable heat exchange and discharge of exhaust gas to the outside without deformation even under high-pressure conditions.

Further, the heat exchange module (90) may be configured to have a sensor (8) installed for measuring parameters of exhaust gas that is received from the damper unit (500), has completed heat exchange, and is discharged to the outside.

In this case, the sensor (8) may be a temperature sensor for measuring the temperature of the discharged exhaust gas, and can measure the temperature of the exhaust gas after heat exchange is completed, and accordingly, induce appropriate adjustment of the degree of heat exchange between the heat exchange module (90) and the exhaust gas.

The foregoing is merely a description of some of the preferred embodiments that can be implemented by the present invention. As is well known, the scope of the present invention should not be construed as being limited to the above embodiments, and it is understood that all technical ideas that share the technical spirit and fundamental principles of the present invention described above are included within the scope of the present invention.

What is claimed is:

1. A substrate processing apparatus comprising:
a heater unit forming a heating space therein;
a processing vessel including a vessel part in which the heater unit is disposed and having an opening formed on a side thereof, and an opening/closing part provided in the vessel part to open and close the opening and having a door opening formed therethrough; and
a damper unit installed in the processing vessel to cover the door opening and transferring exhaust gas discharged from the heating space to the outside through the door opening.

2. The substrate processing apparatus according to claim 1, further comprising:
an inner tube disposed in the heater unit to form the heating space between itself and the heater unit, and forming a processing space for substrate processing therein.

3. The substrate processing apparatus according to claim 1, wherein:
the opening/closing part opens the opening to allow external access to the inside of the processing vessel for maintenance of the damper unit.

4. The substrate processing apparatus according to claim 1, wherein:
the opening/closing part comprises: a flange part protruding from the vessel part at a position corresponding to the opening; and an opening/closing door part installed on the flange part to open and close the opening.

5. The substrate processing apparatus according to claim 4, wherein:
the damper unit has one end coupled to the heater unit so as to communicate with the heating space, and the other end coupled to the opening/closing door part so as to cover the door opening.

6. The substrate processing apparatus according to claim 1, further comprising:
a heat exchange module coupled to the opening/closing part outside the processing vessel so as to communicate with the damper unit through the door opening, and performing heat exchange with the exhaust gas.

7. The substrate processing apparatus according to claim 4, further comprising:
a cooling gas supply unit installed through the opening/closing part to supply cooling gas to the heating space.

8. The substrate processing apparatus according to claim 7, wherein:
the cooling gas supply unit is installed to penetrate the lower side of the flange part.

9. The substrate processing apparatus according to claim 7, wherein:
the cooling gas supply unit comprises:
an external supply pipe installed on the lower side of the flange part to transfer the cooling gas from outside; and
an internal supply pipe installed inside the flange part so as to communicate with the external supply pipe, with one end coupled to the side of the heater unit and the other end coupled to the inner surface of the flange part.

10. The substrate processing apparatus according to claim 9, wherein:
the external supply pipe is formed in an ‘L’ shape in front view with respect to the opening/closing door part.

11. The substrate processing apparatus according to claim 8, wherein:
the cooling gas supply unit is provided as a pair in both lateral directions with respect to the front center of the flange part.

12. The substrate processing apparatus according to claim 4, wherein:
the flange part and the opening/closing door part have a rectangular cross-section corresponding to the damper unit.

13. The substrate processing apparatus according to claim 9, wherein:
the heater unit comprises:
a side insulation part forming the heating space;
a heating part provided on the inner surface of the side insulation part to generate heat according to applied power; and
an upper insulation part provided on the upper end of the side insulation part, having an exhaust flow path formed therein for discharging exhaust gas from the heating space, and coupled to the damper unit.

14. The substrate processing apparatus according to claim 13, wherein:
the internal supply pipe is coupled at the boundary between the side insulation part and the upper insulation part so as to communicate with the heating space.

15. The substrate processing apparatus according to claim 13, wherein:
the internal supply pipe is coupled at a position corresponding to a groove formed on the outer side of the side insulation part with a step inward, and communicating with the heating space.

16. The substrate processing apparatus according to claim 13, wherein:
the damper unit is coupled to the upper insulation part so as to communicate with the exhaust flow path.

17. The substrate processing apparatus according to claim 13, wherein:
the internal supply pipe is disposed below the damper unit inside the flange part.

18. The substrate processing apparatus according to claim 4, further comprising:
a cooling unit installed to surround at least a portion of the flange part.

19. The substrate processing apparatus according to claim 18, wherein:
the cooling unit comprises:
a first cooling pipe installed on the outer surface of the processing vessel and having heat medium flowing therein; and
a second cooling pipe extending from the first cooling pipe and installed to surround at least a portion of the flange part and having heat medium flowing therein.

20. The substrate processing apparatus according to claim 1, wherein:
the internal space between the processing vessel and the heater unit, and the heating space communicate with each other.

21. The substrate processing apparatus according to claim 2, wherein: the inner tube comprises quartz; and the processing vessel comprises SUS.

22. The substrate processing apparatus according to claim 2, wherein:
the internal space between the processing vessel and the heater unit is maintained at higher pressure than the processing space.

23. The substrate processing apparatus according to claim 2, wherein:
the internal space between the processing vessel and the heater unit maintains pressure of 2 ATM or more during at least a portion of the process performed in the processing space.
